(19) United States
(12) Patent Application Publication
(10) Pub. No.: US 2013/0169610 A1
(43) Pub. Date: Jul. 4, 2013

(54) DRIVING CIRCUIT AND DISPLAY DEVICE

(71) Applicant: STMicroelectronics (Shenzhen) R&D Co. Ltd., Shenzhen (CN)

(72) Inventors: Tao Tao Huang, Shenzhen (CN); Meng Wang, Shenzhen (CN)

(73) Assignee: STMicroelectronics (Shenzhen) R&D Co. Ltd., Shenzhen (CN)

(21) Appl. No.: 13/648,826

(22) Filed: Oct. 10, 2012

(30) Foreign Application Priority Data
Dec. 30, 2011 (CN) 201110461491.6

(51) Int. Cl. G09G 5/00; H03K 3/00

(52) U.S. Cl. 345/211; 327/108

(57) ABSTRACT

A driving circuit includes a controller, a converter and a feedback module. The controller receives an input supply at a supply node, and generates a control signal according to the input supply. The converter receive an input signal at an input node and a control signal at a control node, and is configured to convert the input signal to a driving signal in response to the control signal. The driving signal of the converter is feedback by the feedback module to the controller. The input supply is generated from the input signal or the feedback driving signal. The drive circuit may drive a display device.

### PRIORITY CLAIM

This application claims priority to Chinese Application for Patent No. 201110461491.6 filed Dec. 30, 2011, the disclosure of which is incorporated by reference.

### TECHNICAL FIELD

This invention relates generally to electronic circuits, and more particularly to a driving circuit and a display device.

### BACKGROUND

For display devices, such as LCD (Liquid Crystal Display) devices, a DC (Direct Current) driving signal of sufficient driving capability is required to ensure a normal operation of the display devices. The DC driving signal is generally generated from an input supply by a driving circuit and further stored in an output capacitor that is coupled to an output node of the driving circuit. With the output capacitor, the driving circuit is able to maintain the display device supplied in a predetermined voltage level.

To convert the input supply into the DC driving signal, the driving circuit may comprise one or more converters, such as buck converters, boost converters or charge pumps. These converters generally use switched inductors and/or capacitors to generate the DC driving signal. However, when the input supply is disconnected, i.e., when the display device needs to be turned off, there may exist remaining energy at the output node of the driving circuit due to the inductors and/or capacitors. The remaining energy may cause the display device to work in an abnormal state, which decreases the reliability of the display device.

Thus, there is a need for a driving circuit for driving loads, such as display devices, with higher reliability.

### SUMMARY

In one aspect, a circuit comprises a controller, a converter and a feedback module. The controller has a supply node, and is configured to receive an input supply at the supply node and to generate one or more control signals according to the input supply. The converter has an input node and a control node, and is configured to receive an input signal at the input node and the control signal at the control node, and to convert the input signal to a driving signal in response to the control signal. The feedback module is configured to feedback the driving signal of the converter to the controller. The input supply is generated from the input signal or the feedback driving signal.

With the feedback module, the electric energy stored in an output capacitor coupled to the output node of the circuit can be discharged quickly. Therefore, the reliability of a load driven by the circuit can be significantly improved.

In another aspect, there is provided a display device. The display device comprises a display module and the circuit in the previous aspect for driving the display module.

The foregoing has outlined, rather broadly, features of the present disclosure. Additional features of the disclosure will be described, hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 shows a block diagram of a circuit;

FIG. 2a shows a block diagram of a circuit;

FIG. 2b shows the evolution of signals along time at given points of an example of the circuit of FIG. 2a;

FIG. 3 shows a block diagram of a circuit;

FIG. 4 shows a block diagram of a circuit;

FIG. 5 shows a block diagram of a display device.

Corresponding numerals and symbols in different figures generally refer to corresponding parts unless otherwise indicated. The figures are drawn to clearly illustrate the relevant aspects of embodiments of the present disclosure and are not necessarily drawn to scale. To more clearly illustrate certain embodiments, a letter indicating variations of the same structure, material, or process step may follow a figure number.

### DETAILED DESCRIPTION OF THE DRAWINGS

The making and using of embodiments are discussed in detail below. It should be appreciated, however, that the present invention provides many applicable inventive concepts that may be embodied in a wide variety of specific contexts. The specific embodiments discussed are merely illustrative of specific ways to make and use the invention, and do not limit the scope of the invention.

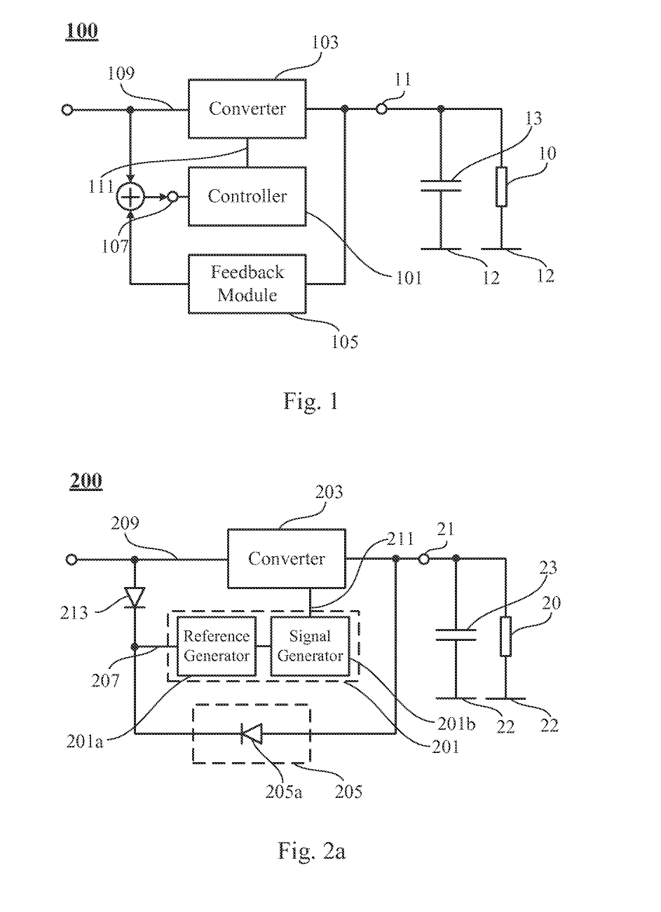

FIG. 1 shows a block diagram of a circuit 100. The circuit 100 is used to drive a load 10 coupled between an output node 11 of the circuit 100 and a reference potential line 12 such as ground. For example, the load 10 may comprise a display device such as an LCD panel or an LED panel, a memory such as ROM (Read Only Memory) or RAM (Random Access Memory), a sensing device such as a touch sensing screen or a touch sensing pad, or a loudspeaker, etc. The circuit 100 is configured to provide a driving signal of a predetermined voltage level with sufficient current driving capability to the load 10. Thus, the load 10 may be maintained in a normal operation state and then properly function. In an embodiment, the circuit 100 further comprises an output capacitor 13 that is coupled between the output node 11 and the reference potential line 12.

As shown in FIG. 1, the circuit 100 comprises a controller 101, a converter 103 and a feedback module 105.

The controller 101 has a supply node 107, and is configured to receive an input supply at the supply node 107 and to generate a control signal according to the input supply.

The converter 103 has an input node 109 and a control node 111, and is configured to receive an input signal at the input node 109, to receive the control signal at the control node 111, and to convert the input signal to a driving signal in response to the control signal.

The feedback module 105 is configured to feedback the driving signal of the converter 103 to the controller 101, and the input supply for the controller 101 is generated from the input signal or the feedback driving signal.

Specifically, the input signal and the driving signal may be DC signals of different voltage levels, and the converter 103 is a DC/DC converter. In some embodiments, the converter 103 may be a boost converter, a buck converter, a buck-boost converter or a charge pump. In some other embodiments, the converter 103 may comprise the combination of the boost converter, the buck converter, the buck-boost converter and the charge pump because the load 10 may require the driving signal to have several components of different voltage levels. For example, the buck converter may be used to generate a component of the driving signal lower than the input signal. The boost converter may be used to generate another component of the driving signal greater than the input signal. It will be readily understood by those of ordinary skills in the art, the converter 103 may be other suitable devices for providing driving signals, such as LDO (Low Drop Out) regulator.

In some embodiments, the boost converter, the buck converter or the buck boost converter comprises a switched inductor-diode network or a switched inductor network, which receives the input signal at the input node 109 and outputs the input signal at the output node 11. The connection of the inductor and the diode depends on one or more switches within the switched inductor-diode network. Specifically, the switch receives the control signal at the control node 111, which causes the switch to be turned on or off, thereby changing the connection between the inductor and the diode. In some other embodiments, the charge pump comprises a switched capacitor network have one or more switches and one or more capacitors. The connection of the switched capacitor network depends on the one or more switches within the switched inductor-diode network.

The feedback module 105 feeds back the driving signal to the supply node 107 so as to at least partially supply the controller 101. In an embodiment, the feedback module 105 is arranged such that a current is prevented from flowing from the supply node 107 to the output node 11 through the feedback module 105. The controller 101 also receives the input signal at the supply node 107. Thus, the input supply is selected from the input signal or the driving signal that is fed back by the feedback module 105. In an embodiment, the input signal and the feedback driving signal is wired-or connected. In this way, when the input signal is greater than the feedback driving signal, the voltage level at the supply node 107 is equal to the voltage level of the input signal, then the controller 101 is supplied with the input signal. When the input signal is lower than the feedback driving signal, the voltage level at the supply node 107 is equal to the voltage level of the feedback driving signal, then the controller 101 is supplied with the feedback driving signal.

Specially, when the input signal is initially disconnected, the voltage level at the output node 12 will be higher than the voltage level at the supply node 107. Thus, the electric energy stored in the converter 103 or the output capacitor 13 will be fed back from the output node 11 to the supply node 107. Therefore, the controller 101 will be kept on for a period. During the period, the controller 101 will discharge the stored electric energy so as to prevent the electric energy from supplying to the load 10. In this way, the circuit 100 can effectively prevent the load 10 from working under an unstable power supply, thereby improving the reliability and safety of the load 10.

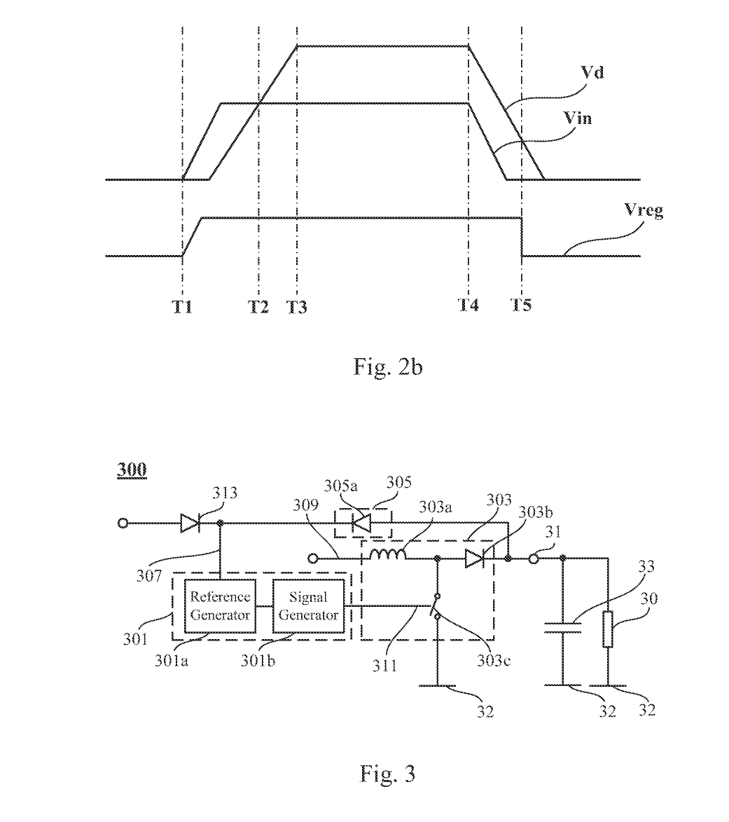

FIG. 2a shows a block diagram of a circuit 200. The circuit 200 is used to drive a load 20 coupled between an output node 21 of the circuit 200 and a reference potential line 22 such as ground.

As shown in FIG. 2a, the circuit 200 comprises a controller 201, a converter 203 and a feedback module 205.

The controller 201 comprises a reference generator 201a and a signal generator 201b. The reference generator 201 a is configured to generate one or more reference signals according to an input supply that is received at a supply node 207 of the controller 201. The signal generator 201b is configured to generate a control signal being supplied with the one or more reference signals. The control signal is provided to the converter 203 and then used to control the operation of the converter 203. In some embodiments, the reference generator 201a may comprise a regulator, an oscillator, a current bias generator or combination thereof. In detail, the regulator is used to generate a positive DC power supply for the controller 201. The oscillator is used to generate a clock signal for the controller 201. The current bias generator is used to generator a current bias for the controller 201. Being supplied with the reference signals provided by the reference generator 201a, the signal generator 201b can properly work and then generate the control signal. In an embodiment, the control signal has a specific logic sequence that is suitable for controlling the operation of switches in the converter 203, thereby controlling the operation of the converter 203.

The feedback module 205 comprises a first diode 205a with a first anode and a first cathode. The first anode is coupled to the output node 21, and the first cathode is coupled to a supply node 207 of the controller 201. When the voltage level at the output node 21 is higher than the voltage level at the supply node 207, the first diode 205a can feedback a driving signal at the output node 21 to the supply node 207 so as to supply the controller 201. Further, the first diode 205a can prevent a current flowing from the supply node 207 to the output node 21, because the first diode 205a only allows current to pass in its forward direction while blocking current in its reverse direction. In some other embodiments, the feedback module 205 may be a bipolar transistor or other suitable devices.

In the embodiment, the circuit 200 further comprises a second diode 213 with a second anode and a second cathode. The second anode is configured to receive an input signal, and the second cathode is coupled to the supply node. Thus, the input signal can be provide to the controller 201 as its input supply. Specifically, the first diode 205a and the second diode 213 is such arranged that the input signal and the feedback driving signal is wired-or connected. In this way, the controller 201 may be supplied with the input signal or the feedback driving signal according to their voltage levels.

FIG. 2b shows the evolution of signals along time at given points of an example of the circuit 200. Hereinafter, the working of the circuit 200 shown in FIG. 2a will be elaborated. In the example, the reference generator comprises a regulator for providing a regulating signal to the signal generator, and the converter is a boost converter.

As shown in FIG. 2b, curve Vᵢₙ shows the variation of the input signal at the input node along time, curve V_{d} shows the variation of the driving signal at the output node along time, and curve V_{reg} shows the variation of the regulating signal along time. At time T₁, the input signal is initially connected to the circuit 200. Accordingly, the regulating signal and the driving signal increase with the input signal. From time T₁ to time T₂, the driving signal is lower than the input signal, then the regulator is supplied with the input signal. From time T₂ to time T₃, the converter 203 continuously boosts the driving signal such that the driving signal increases to a voltage level higher than the voltage level of the input signal after time T₂. From time T₃ to time T₄, the driving signal is maintained substantially stable so as to supply the load 20. During the period from time T₂ to time T₄, the regulator is supplied with the driving signal that is fed back by the feedback module 205, as the driving signal is higher than the input signal. At time T₄, the input signal is initially disconnected. The driving signal immediately decreases with the input signal as the converter 203 cannot receive the input signal. Meanwhile, the regulator is still supplied with the driving signal, which keeps the regulator working normally until time T₅. In this way, the electric energy stored in the converter 203 and the output capacitor 23 can be discharged through the regulator quickly. Therefore, the period that the load 20 operates in an abnormal state is significantly reduced, which improve the reliability of the load 20.

FIG. 3 shows a block diagram of a circuit 300. The circuit 300 is used to drive a load 30 which is coupled between an output node 31 of the circuit 300 and a reference potential line 32.

As shown in FIG. 3, the circuit 300 comprises a controller 301, a converter 303 and a feedback module 305. In the embodiment, the converter 303 is a boost converter whose output signal is greater than its input signal.

The controller 301 has a supply node 307, and is configured to receive an input supply at the supply node 307 and to generate a control signal according to the input supply. In the embodiment, the controller 301 has a reference generator 301a and a boost signal generator 301b.

The boost converter 303 has an input node 309 and a control node 311, and is configured to receive an input signal at the input node 309, to receive the control signal at the control node 311, and to convert the input signal to a driving signal in response to the control signal. In the embodiment, the boost converter 303 comprises a first inductor 303a, a third diode 303b and a first switch 303c.

The feedback module 305 is configured to feedback the driving signal of the converter 303 to the controller 301. In the embodiment, the feedback module 305 comprises a first diode 305a. Moreover, the circuit 300 further comprises a second diode 313, the input signal is provided to the controller 301 and the converter 303 via the second diode 313. The first diode 305a and the second diode 313 is wired-or connected such that the input supply of the controller 301 is generated from the input signal or the feedback driving signal.

In detail, the first diode 305a has a first anode and a first cathode. The first anode is coupled the output node 31, and the first cathode is coupled to the supply node 307. The second diode 313 has a second anode and a second cathode. The second anode is configured to receive the input signal, and the second cathode is coupled to the supply node 307. The first inductor 303a has a first node and a second node, wherein the first node is configured to receive the input signal. The first switch 303c has a third node, a fourth node and a first control node. The third node is coupled to the second node of the first inductor 303a, the fourth node is coupled to the reference potential line 32, and the first control node is configured to receive the control signal. The third diode 303b has a third anode and a third cathode. The third anode is coupled to the second node and the third node, and the third cathode is coupled to the output node 31 so as to output the driving signal converted by the boost converter 303.

When the input signal is initially disconnected, the voltage level at the output node 31 will be higher than the voltage level at the supply node 307. Thus, the electric energy stored in the boost converter 303 or the output capacitor 33 will be fed back from the output node 31 to the supply node 307. The controller 301 will discharge the stored electric energy so as to prevent the electric energy from supplying to the load 30. In this way, the period that the load 30 operates in an abnormal state is significantly reduced, thereby improving the reliability of the load 30.

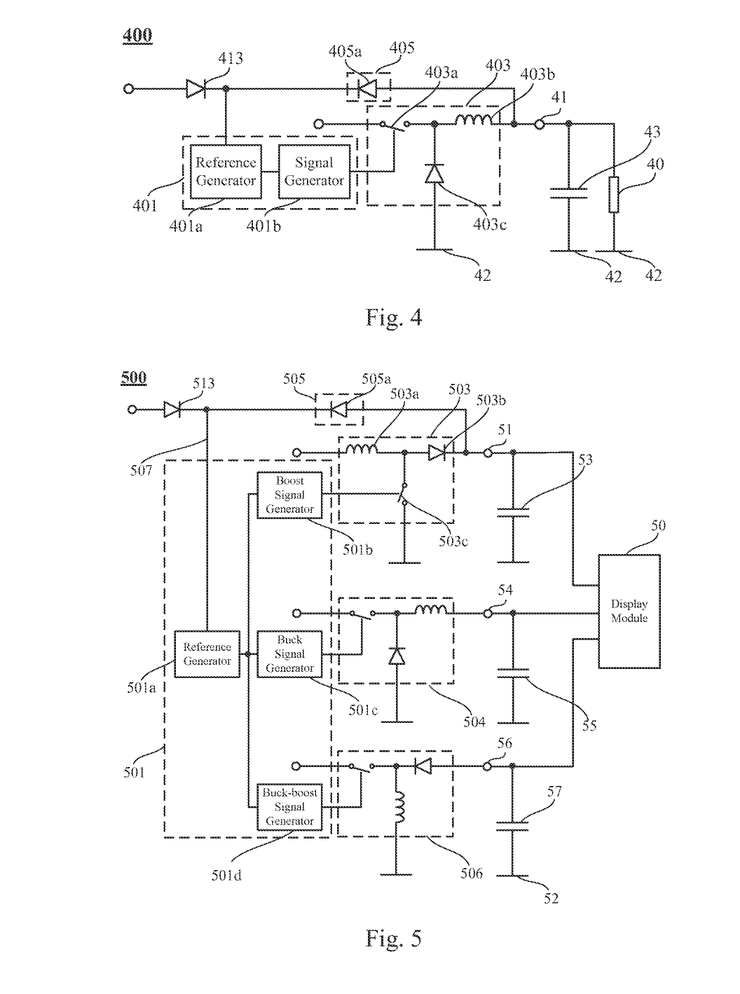

FIG. 4 shows a block diagram of a circuit 400. The circuit 400 is used to drive a load 40 which is coupled between an output node 41 of the circuit 400 and a reference potential line 42.

As shown in FIG. 4, the circuit 400 comprises a controller 401, a converter 403 and a feedback module 405. In the embodiment, the converter 403 is a buck converter whose output signal is lower than its input signal.

In the embodiment, the controller 401 comprises a reference generator 401a and a buck signal generator 401b. The buck converter 403 comprises a second inductor 403b, a second switch 403a and a fourth diode 403c.

The feedback module 405 comprises a first diode 405a. The first diode 405a is wired-or connected with a second diode 413 such that an input supply of the controller 401 is generated from the input signal or the feedback driving signal.

In detail, the first diode 405a has a first anode and a first cathode. The first anode is coupled to the output node 41, and the first cathode is coupled to the supply node 407. The second diode 413 has a second anode and a second cathode. The second anode is configured to receive the input signal, and the second cathode is coupled to the supply node 407. The second switch 403a has a fifth node, a sixth node and a second control node. The fifth node is configured to receive the input signal, and the second control node is configured to receive a control signal from the signal generator 401b. The second inductor 403b has a seventh node and a eighth node. The seventh node is coupled to the sixth node, and the eighth node is coupled to the output node 41 and configured to output the driving signal. The fourth diode 403c has a fourth anode and a fourth cathode. The fourth anode is coupled to the reference potential line 42, and the fourth cathode is coupled to the sixth node and the seventh node.

When the input signal is initially disconnected, the voltage level at the output node 41 will be higher than the voltage level at the supply node 407. Thus, the electric energy stored in the buck converter 403 or the output capacitor 43 will be fed back from the output node 41 to the supply node 407. The controller 401 will discharge the stored electric energy so as to prevent the electric energy from supplying to the load 40. In this way, the period that the load 40 operates in an abnormal state is significantly reduced, thereby improving the reliability and safety of the load 40.

FIG. 5 shows a block diagram of a display device.

As shown in FIG. 5, the display device 500 comprises a display module 50 such as an LCD panel or an LED panel. The display module 50 is driven by a driving circuit. In some embodiments, to ensure a normal operation of the display module 50, driving signals of various voltage levels are required. Therefore, the driving circuit comprises a boost converter 503, a buck converter 504 and a buck-boost converter 506, which are configured to convert an input signal to the driving signals of various voltage levels. Specifically, the boost converter 503 outputs a first driving signal at a first output node 51. The driving circuit also comprises a first output capacitor 53 that is coupled between the first output node 51 and a reference potential line 52. The buck converter 504 outputs a second driving signal at a second output node 54. The driving circuit also comprises a second output capacitor 55 that is coupled between the second output node 54 and the reference potential line 52. The buck-boost converter 506 outputs a third driving signal at a third output node 56. The driving circuit also comprises a third output capacitor 57 that is coupled between the third output node 56 and the reference potential line 52. In some other embodiments, the driving circuit may comprise charge pumps or other suitable devices for generating the driving signals.

The driving circuit comprises a controller 501. The controller 501 comprises a reference generator 501a, a boost signal generator 501b, a buck signal generator 501c and a buck-boost signal generator 501d. The reference generator 501a is configured to generate one or more reference signals, such as a DC reference voltage, a clock signal, a current bias signal, etc., according to an input supply that is received at a supply node 507. The reference signals are further provided to the boost signal generator 501b, the buck signal generator 501c and the buck-boost signal generator 501d. Being supplied with the reference signals, the boost signal generator 501b, the buck signal generator 501c and the buck-boost signal generator 501d generate different control signals and then provide the control signals to switches within the respective converters coupled thereto. Therefore, the work of the converters 503, 504 and 506 can be controlled by the respective control signals.

The driving circuit comprises a feedback module 505 coupled between the first output node 51 and the supply node 507. The feedback module 505 feedbacks the first driving signal to the supply node 507 so as to at least partially supply the reference generator 501a. In the embodiment, the feedback module 505 may be a first diode 505a with a first anode and a second cathode. The first anode is coupled to the first output node 51, and the first cathode is coupled to the supply node 507. When the voltage level at the first output node 51 is higher than the voltage level at the supply node 507, the first diode 505a can feedback the first driving signal to the supply node 207. Further, the first diode 505a can prevent a current flowing from the supply node 507 to the first output node 51, because the first diode 505a only allows current to pass in its forward direction while blocking current in its reverse direction. In the embodiment, the driving circuit further comprises a second diode 513, which is wired-or connected with the first diode 505a.

From the foregoing, when the input signal is initially disconnected, the voltage level at the first output node 51 will be higher than the voltage level at the supply node 507. Thus, the electric energy stored in the boost converter 503 or the output capacitor 53 will be fed back from the output node 51 to the supply node 507. The reference generator 501a will discharge the stored electric energy so as to prevent the electric energy from supplying to the display module 50. In this way, the period that the display module 50 operates in an abnormal state is significantly reduced, thereby improving the reliability and safety of the display device 500.

Further, in some embodiments, the feedback module 505 can be coupled between other output nodes of the driving circuit and the supply node 507. In other words, the driving circuit can be arranged to select which converter is first discharged according to practical applications, because the voltage level of the output node to which the feedback module 505 drops faster than those uncoupled output nodes. Therefore, the power off sequence of components within the display module 50 can be adjusted such that the reliability of the display device 500 can be further improved.

It will also be readily understood by those skilled in the art that materials and methods may be varied while remaining within the scope of the present invention. It is also appreciated that the present invention provides many applicable inventive concepts other than the specific contexts used to illustrate embodiments. Accordingly, the appended claims are intended to include within their scope such processes, machines, manufacturing, compositions of matter, means, methods, or steps.

What is claimed is:

1. A circuit, comprising:
a control circuit having an input node coupled to an input supply node and having an output node, the control circuit configured to generate a control signal at the output node;
a converter circuit having an input node coupled to the input supply node and having a control node coupled to receive the control signal, the converter circuit configured to convert an input signal received at the input node to a driving signal in response to the received control signal; and
a feedback circuit configured to feed the driving signal back to the input node of the control circuit.

2. The circuit of claim 1, further comprising a wired-or circuit configured to couple the input supply node and the fed back driving signal to the input node of the control circuit.

3. The circuit of claim 1, wherein the feedback circuit comprises a first diode having a first anode coupled to receive the driving signal and a first cathode coupled to the input node of the control circuit.

4. The circuit of claim 3, further comprising a second diode having a second anode coupled to the input supply node and a second cathode coupled to the input node of the control circuit.

5. The circuit of claim 1, wherein the control circuit comprises:
a reference generator configured to generate one or more reference signals; and
a signal generator configured to generate the control signal in response to said one or more reference signals.

6. The circuit of claim 5, wherein the reference generator comprises at least one of a regulator, an oscillator, and a current bias generator.

7. The circuit of claim 1, wherein the converter circuit is selected from the group consisting of: a boost converter, a buck converter, a buck-boost converter, or a charge pump.

8. The circuit of claim 1, wherein the converter circuit comprises a boost converter, said boost converter comprising:
a first inductor with a first node and a second node, wherein the first node is coupled to the input supply node;
a first switch with a third node, a fourth node and a first control node, wherein the third node is coupled to the second node, the fourth node is coupled to a reference potential line, and the first control node is configured to receive the control signal; and
a third diode having a third anode coupled to the second node and the third node and a third cathode configured to output the driving signal.

9. The circuit of claim 1, wherein the converter circuit comprises a buck converter, said buck converter comprising:
a second switch with a fifth node, a sixth node and a second control node, wherein the fifth node is coupled to the input supply node, and the second control node is configured to receive the control signal;
a second inductor with a seventh node and a eighth node, wherein the seventh node is coupled to the sixth node and the eighth node is configured to output the driving signal; and;
a fourth diode having a fourth anode coupled to a reference potential line and a fourth cathode coupled to the sixth node and the seventh node.

10. The circuit of claim 1, wherein the converter circuit comprises a charge pump having a switched capacitor network, wherein the switched capacitor network comprises one or more switches and one or more capacitors.

11. The circuit of claim 1, further comprising an output capacitor coupled to receive the driving signal.

12. The circuit of claim 1, further comprising a display device includes a display module coupled to receive the driving signal.

13. The circuit of claim 12, wherein the display module is selected from the group consisting of an LCD panel or an LED panel.

14. A circuit, comprising:
a voltage conversion circuit having an input coupled to a voltage source node, a switching circuit controlled by a control signal, and having an output configured to output a converted voltage;
a control circuit having an input supply node, the control circuit configured to generate the control signal;
a feedback circuit coupled between the output of the voltage conversion circuit and the input supply node of the control circuit;
a supply circuit configured to supply voltage from the voltage source node to the input supply node of the control circuit.

15. The circuit of claim 14, wherein the supply circuit comprises a diode circuit having an anode coupled to the voltage source node and a cathode coupled to the input supply node of the control circuit.

16. The circuit of claim 14, wherein the feedback circuit comprises a diode circuit having an anode coupled to output of the voltage conversion circuit and a cathode coupled to the input supply node of the control circuit.

17. The circuit of claim 14, further comprising a capacitor coupled between the output of the voltage conversion circuit and a reference supply node.

18. The circuit of claim 17, further comprising a load circuit coupled between the output of the voltage conversion circuit and a reference supply node.

19. The circuit of claim 14, wherein the supply circuit comprises a summing circuit configured to sum a voltage from the voltage source node with the converted voltage from the output of the voltage conversion circuit to generate a supply voltage for application to the input supply node of the control circuit.

20. The circuit of claim 14, wherein the voltage conversion circuit is selected from the group consisting of: a boost converter, a buck converter, a buck-boost converter, or a charge pump.
